(19) United States
(12) Patent Application Publication
(10) Pub. No.: US 2024/0349427 A1
(43) Pub. Date: Oct. 17, 2024

(54) MULTILAYER WIRING SUBSTRATE AND METHOD OF MANUFACTURING THE MULTILAYER WIRING SUBSTRATE

(71) Applicant: TOPPAN HOLDINGS INC., Tokyo (JP)

(72) Inventor: Takehisa TAKADA, Tokyo (JP)

(73) Assignee: TOPPAN HOLDINGS INC., Tokyo (JP)

(21) Appl. No.: 18/755,615

(22) Filed: Jun. 26, 2024

Related U.S. Application Data
(63) Continuation of application No. PCT/JP2022/043661, filed on Nov. 28, 2022.

(30) Foreign Application Priority Data
Dec. 28, 2021 (JP) 2021-214836

(51) Int. Cl. H05K 1/11; H05K 1/03; H05K 3/40

(52) U.S. Cl. CPC H05K 1/115; H05K 1/0306; H05K 3/4038; H05K 2203/0307; H05K 2203/0723; H05K 2203/107

(57) ABSTRACT

A multilayer wiring substrate including a glass substrate provided with a through electrode, in which a bottom surface part of the through electrode provided to the glass substrate contains an unevenness in which an absolute value of a height difference from a first surface of the glass substrate is ±0.5 μm or more and 5 μm or less. For manufacturing this, a glass substrate is irradiated with a laser, a modified part reaching a first surface is formed in the glass substrate, and an unevenness is formed on the first surface of the glass substrate. Then, a hydrofluoric acid resistant metal layer and/or a first seed layer on each of which a shape of the unevenness is transferred is formed. Thereafter, a through glass via is formed by hydrofluoric acid, and then a second seed layer on which the uneven shape is transferred is formed in the through glass via.

### CROSS-REFERENCE TO RELATED PATENT APPLICATIONS

This application is a continuation application filed under 35 U.S.C. § 111(a) claiming the benefit under 35 U.S.C. §§ 120 and 365(c) of International Patent Application No. PCT/JP2022/043661, filed on Nov. 28, 2022, which is based upon and claims the benefit to Japanese Patent Application No. 2021-214836 filed on Dec. 28, 2021, the disclosures of all which are incorporated herein by reference in their entirety.

### TECHNICAL FIELD

The present invention relates to a multilayer wiring substrate and a method of manufacturing the multilayer wiring substrate.

### BACKGROUND

A relay board called an interposer has been used for mounting large-scale integration (LSI) on a flip chip-ball grid array (FC-BGA) or a printed circuit board.

In recent years, attention has been given to a technology in which an inexpensive and large-area glass substrate is used as a core material of this interposer, and a through glass via (TGV) is formed thereto to form an interposer.

However, the formation of a through glass via to a glass substrate deteriorates the mechanical strength of the glass substrate. Especially, when the thickness of glass is 300 μm or less, glass cracking may occur in, for example, a conveyance step for forming a conductive part such as a circuit on the interposer.

To address this concern, PTL 1 discloses a method of irradiating a glass substrate with laser to form a modified part, thereafter, forming a first conductive part on the glass substrate, and thereafter forming a through glass via to the glass substrate.

According to the technology of PTL 1, there is an advantage in that handling of a substrate is facilitated, because performing a laser treatment before forming a first conductive part on a glass substrate prevents, for example, the first conductive part on the glass substrate from being damaged by processing heat, and forming a through glass via after forming the first conductive part on the glass substrate can prevent glass cracking.

### CITATION LIST

[Patent Literature] PTL 1: WO 2016/051781.

### SUMMARY OF THE INVENTION

### Technical Problem

PTL 1 considers the prevention of damage to the first conductive part caused by processing heat and the prevention of cracking in the conveyance step. However, sufficient consideration is not given in terms of the connectivity between a conductive layer provided to the through glass via and the first conductive part, particularly the improvement of thermal shock resistance as a through electrode. Therefore, an object of the present invention is to provide a multilayer wiring substrate that improves thermal shock resistance of a through electrode and has high reliability.

### Solution to Problem

For solving the above-described problem, one representative multilayer wiring substrate of the present invention is a multilayer wiring substrate that includes a glass substrate provided with a through electrode, in which a bottom surface part of the through electrode provided to the glass substrate has an unevenness in which an absolute value of a height difference from a first surface of the glass substrate is ±0.5 μm or more and 5 μm or less.

Further, one representative method of manufacturing a multilayer wiring substrate of the present invention for solving the above-described problem includes:
a first step of irradiating a glass substrate having a first surface and a second surface with a laser to form a modified part reaching the first surface in the glass substrate and form, on the first surface of the glass substrate, an unevenness having a width of 0.5 μm or more and 20 μm or less;
a second step of forming, on the first surface of the glass substrate, a hydrofluoric acid resistant metal layer and/or a first seed layer on each of which the unevenness is transferred and formed;
a third step of forming a wiring pattern on an upper side of the hydrofluoric acid resistant metal layer and/or the first seed layer;
a fourth step of etching the modified part from the second surface of the glass substrate using an etching liquid to form a through glass via;
a fifth step of forming, on a surface of the through glass via, a second seed layer on which the unevenness is transferred and formed; and
a sixth step of energizing the second seed layer to perform an electrolytic plating treatment.

### Advantageous Effects of the Invention

According to the present invention, there can be provided a multilayer wiring substrate that improves thermal shock resistance of a through electrode and has high reliability.

Problems, structures, and effects other than those described above will be clarified by Description of the Embodiments below.

### BRIEF DESCRIPTION OF THE DRAWINGS

FIG. 1 is a cross-sectional view of a multilayer wiring substrate according to a first embodiment of the present disclosure.

FIGS. 2(a)-2(c) are views illustrating a shape of an unevenness.

FIGS. 3(a)-3(j) are views of cross-sectional shapes of modified examples of a shape of an unevenness.

FIGS. 4(a)-4(d) are views of plane shapes of modified examples of a shape of an unevenness.

FIGS. 5(a)-5(c) are views for explaining manufacturing steps of Example 1.

FIGS. 6(d)-6(f) are views for explaining manufacturing steps of Example 1.

FIGS. 7(g)-7(k) are views for explaining manufacturing steps of Example 1.

FIG. 8 is a cross-sectional view of a multilayer wiring substrate of Example 1.

FIGS. 9(a)-9(d) are views for explaining a detailed structure of an unevenness.

FIGS. 10(f)-10(h) are views for explaining a detailed structure of an unevenness.

FIGS. 11(a) and 11(b) are views for explaining effects in an electrolytic plating step.

FIGS. 12(a)-12(c) are views for explaining a laser modifying step of Example 5.

FIG. 13 is a plan view of a test pattern.

### DETAILED DESCRIPTION

Hereinafter, with reference to the drawings, the embodiments of the present invention will be described. It is noted that the present invention is not limited by the embodiments. Further, in the descriptions of the drawings, identical portions are given identical reference signs.

When there are a plurality of constituents having identical or similar functions, descriptions may be given by attaching different letters to identical reference signs. Further, when it is not necessary to distinguish the plurality of constituents, descriptions may be given by omitting the attached letters.

Regarding the positions, sizes, shapes, ranges, and the like of the constituents illustrated in the drawings, actual positions, sizes, shapes, ranges, and the like of the constituents may not be illustrated for facilitating the understanding of the invention. Therefore, the present invention is not necessarily limited to the positions, sizes, shapes, ranges, and the like disclosed in the drawings.

It is noted that in the present disclosure, a “surface” may indicate not only a surface of a plate-like member but also an interface of a layer that is contained in a plate-like member and substantially parallel to the surface of the plate-like member. Further, an “upper surface” and a “lower surface” indicate surfaces illustrated on the upper side and on the lower side on the drawing when a plate-like member or a layer contained in a plate-like member is illustrated in the drawing. It is noted that the “upper surface” and the “lower surface” may also be referred to as a “first surface” and a “second surface”.

Further, a “side surface” indicates the portion of the thickness of a surface or a layer in a plate-like member or a layer contained in a plate-like member. Furthermore, a combination of a part of the surface and the side surface may be called an “end part”.

Further, an “upper side” indicates the direction of a vertical upper side when a plate-like member or a layer is horizontally placed. Furthermore, an “upper side” and a “lower side” opposite an “upper side” may be called a “Z-axis plus direction” and a “Z-axis minus direction”, and a horizontal direction may be called an “X-axis direction” and a “Y-axis direction”.

Furthermore, a distance in a Z-axis direction is referred to as a “height”, and a distance on an XY plane defined by an X-axis direction and a Y-axis direction is referred to as a “width”.

Further, the “through electrode provided to the glass substrate” indicates a conductive path provided for electrical conduction between a first surface and a second surface of a glass substrate when the glass substrate is used as a part of a multilayer wiring substrate, and the glass substrate is not necessarily completely penetrated with a single conductive material. When the conductive channel from the first surface and the conductive channel from the second surface are connected to each other, it is included in the through electrode. Furthermore, the form of the through electrode includes both a filled type in which a through glass via (containing either a bottomed form or a completely penetrating form) is filled with a conductive material and a conformal type in which only a side wall portion of a through glass via is covered with a conductive material.

In addition, the through electrode in the present disclosure is based on the assumption that the shape on the outermost side is substantially a cylindrical column shape, a conical column shape, or a pyramid column shape. Therefore, the through electrode has a “side wall part” having an angle of about 50° to 130° with respect to the first or second surface of the glass substrate and a “bottom surface part” constituted by a layer substantially parallel to the first surface or the second surface of the glass substrate.

Further, an “adjacent layer” includes not only a layer in direct contact with a certain layer but also a layer that has some intervening layer(s) between it and the other layer.

Further, a “conforming unevenness” indicates that the unevenness formed on a base and the unevenness formed on, for example, a layer on the upper side or on the lower side of the base have a common element related to the position on the XY plane, shape, size, and the like, and is not necessarily limited to having the same position, shape, and size as those of the uneven shape of the base.

Furthermore, the “unevenness is transferred and formed” indicates that the shape of the unevenness formed on a base is formed on, for example, a layer formed on the upper side or on the lower side of the base such that the shapes are the same or similar, or the presence or absence of an unevenness is common, and the formed shape is not necessarily limited to the same shape as the uneven shape of the base.

Further, a “plane shape” or a “plane view” indicates a shape when a surface or a layer is visually confirmed from the upper side. Furthermore, a “cross-sectional shape” or a “cross-sectional view” indicates a shape when visually confirmed from a horizontal direction when a plate-like member or a layer is cut in a specific direction.

Furthermore, a “center part” indicates a center part that is not a peripheral part of a surface or a layer. In addition, a “center direction” indicates a direction from a peripheral part of a surface or a layer toward a center in a plane shape of a surface or a layer.

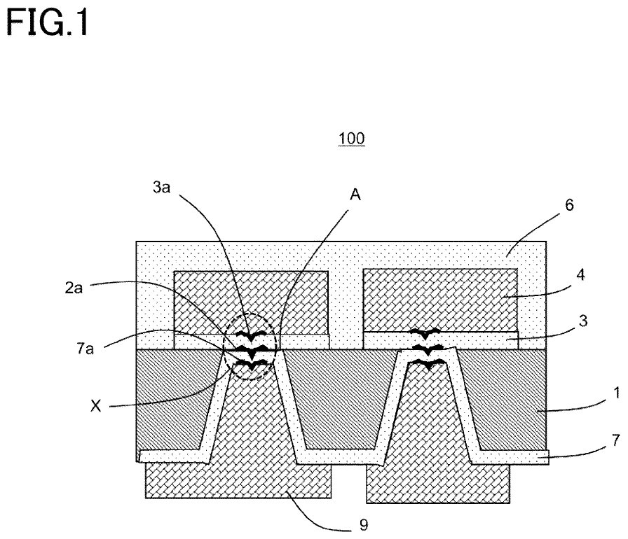

Next, with reference to FIG. 1, a multilayer wiring substrate according to the embodiments of the present disclosure will be described.

### First Embodiment

FIG. 1 is a view illustrating an example of a structure of a multilayer wiring substrate 100 according to a first embodiment of the present disclosure. As illustrated in FIG. 1, the multilayer wiring substrate 100 is configured such that a second seed layer 7 is deposited on a through glass via (not illustrated) provided to a glass substrate 1, and the second seed layer is used to form a through electrode 9 by electrolytic plating or the like.

On the other hand, a hydrofluoric acid resistant metal layer 3 is provided on the upper side of a bottom surface A of the through glass via. A wiring layer 4 is provided on the upper side of the hydrofluoric acid resistant metal layer. It is noted that a first seed layer (not illustrated) may be provided between the hydrofluoric acid resistant metal layer 3 and the wiring layer 4. The hydrofluoric acid resistant metal layer 3 and the wiring layer 4 are patterned to serve as wiring on the upper surface of the glass substrate 1 and covered with an insulating resin 6.

In the first embodiment, an unevenness 2a having a height of 0.5 μm or more and 5 μm or less is provided on the surface of the bottom surface part A of a through electrode provided to the glass substrate 1. In conformity with this uneven shape, an unevenness 3a is also formed on the hydrofluoric acid resistant metal layer 3, and an unevenness 7a is also formed on the second seed layer 7. The present invention can improve, for example, the thermal shock resistance of the through electrode by an unevenness X formed in the bottom surface part including these multiple layers.

It is noted that when a first seed layer (not illustrated) is provided between the hydrofluoric acid resistant metal layer 3 and the wiring layer 4, an uneven shape is also formed on the first seed layer.

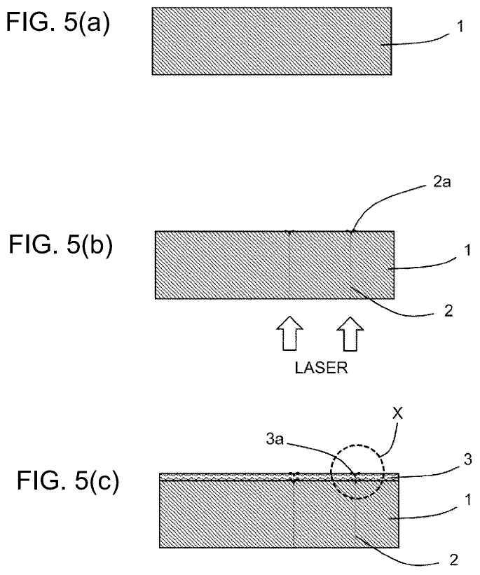

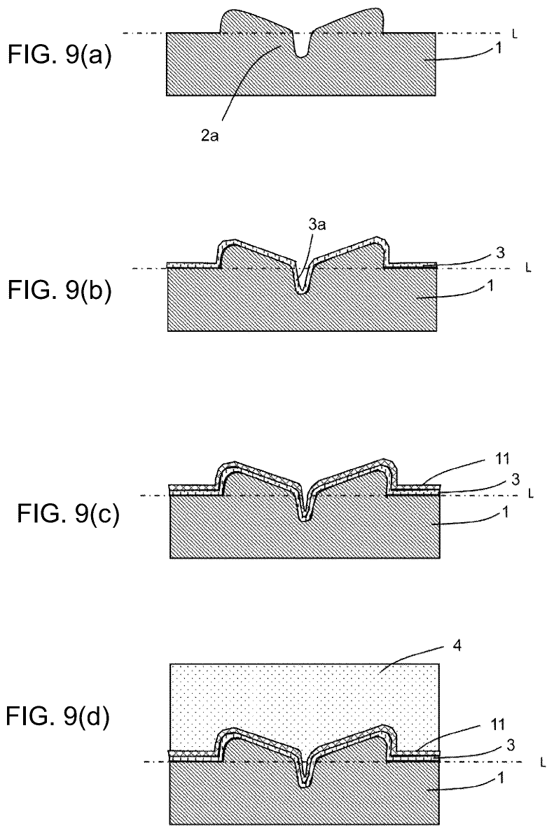

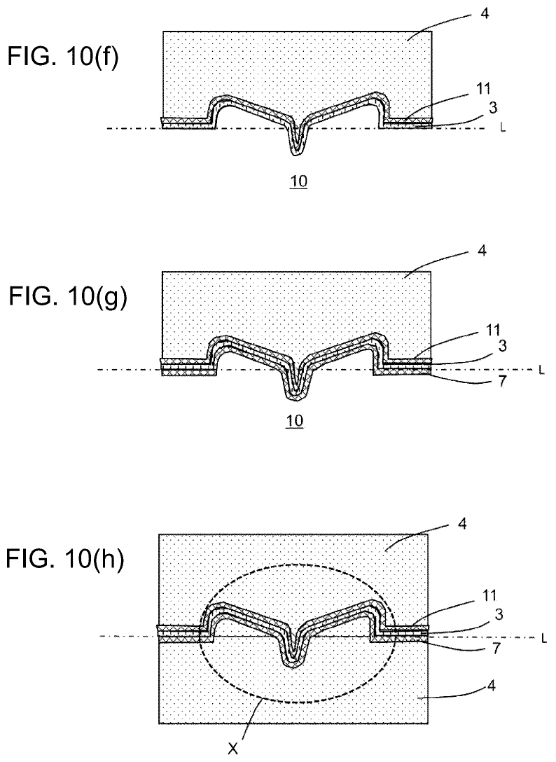

Further, the unevenness 2a, the unevenness 3a, and the unevenness 7a in FIG. 1, FIGS. 5(a)-5(c), and FIGS. 6(d)-6(f) to 8 are schematically and simply expressed as an unevenness, and more concrete shapes of the unevenness in the bottom surface part will be described in FIGS. 9(a)-9(d) and FIGS. 10(f)-10(h).

The unevenness 3a formed on the hydrofluoric acid resistant metal layer 3 and the unevenness 7a formed on the second seed layer 7 do not necessarily have a completely identical shape to that of the unevenness 2a formed on the surface of the bottom surface part A of the through electrode, but the unevenness 2a, the unevenness 3a, and the unevenness 7a conform to one another in the positional relationship on the XY plane and the shape. As described later, this is attributable to the manufacturing steps being related to one another, like when the unevenness 3a and the unevenness 7a are transferred and formed from the previously formed unevenness 2a or when the unevenness 2a and the unevenness 3a are previously formed at the same time, and then the unevenness 7a is transferred and formed from the unevenness 2a.

### <Uneven Shape>

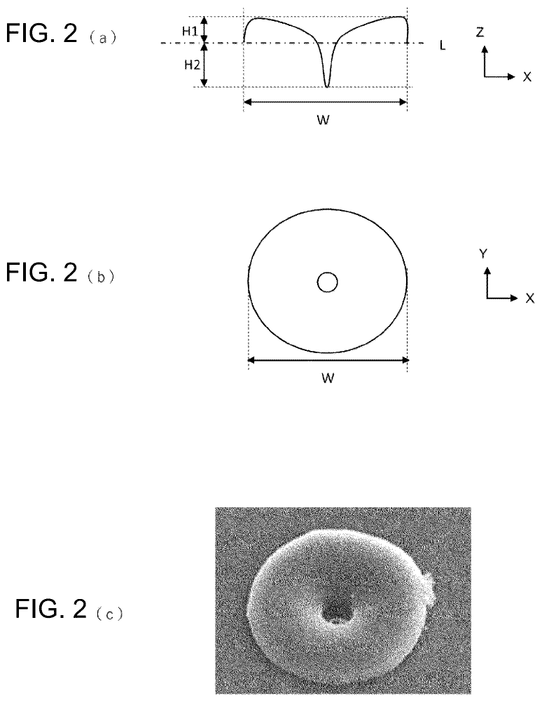

Next, an example of the shape of the unevenness 2a will be described with reference to FIGS. 2(a)-2(c). FIG. 2(a) is a view illustrating a cross-sectional shape of the unevenness 2a, and FIG. 2(b) is a view illustrating a plane shape of the unevenness 2a.

Further, FIG. 2(c) is an electron microscope photograph of the unevenness 2a (photographing conditions: device: scanning electron microscope SU8020, acceleration voltage: 10 KV, magnification: ×10000).

In FIG. 2(a), line segment L denotes the level in the Z-axis direction of the bottom surface A, i.e., the level of a first surface of the glass substrate; H1 is a maximum swelling height of the unevenness; H2 is a maximum concave depth of the unevenness; and W is a width of the unevenness.

As the size of the unevenness, firstly in the height direction, each of H1 and H2 is preferably 0.5 to 5 μm. That is, it is desirable that the absolute value of a height difference from the first surface of the glass substrate is ±0.5 μm or more and 5 μm or less.

When H1 or H2 is more than 5 μm, throwing power of the seed layer to the unevenness deteriorates, and laser power for forming this increases, which causes the occurrence of cracks in the glass substrate.

Further, when H1 or H2 is less than 0.5 μm, later-described effects produced by the presence of an unevenness undesirably decrease.

Next, the width W of the unevenness is favorably 0.5 to 20 μm. It is noted that for the width of the unevenness, W is a maximum distance, in the Z-axis direction, to a position where the glass surface shape has changed from the level of the bottom surface part A in the cross-sectional shape of the unevenness. When W is more than 20 μm, laser power for forming this increases, which unsuitably causes cracks to be likely to occur in the glass substrate. Further, Further, when W is less than 0.5 μm, the later-described effects produced by the presence of the unevenness unsuitably decrease.

### <Modified Examples of Uneven Shape>

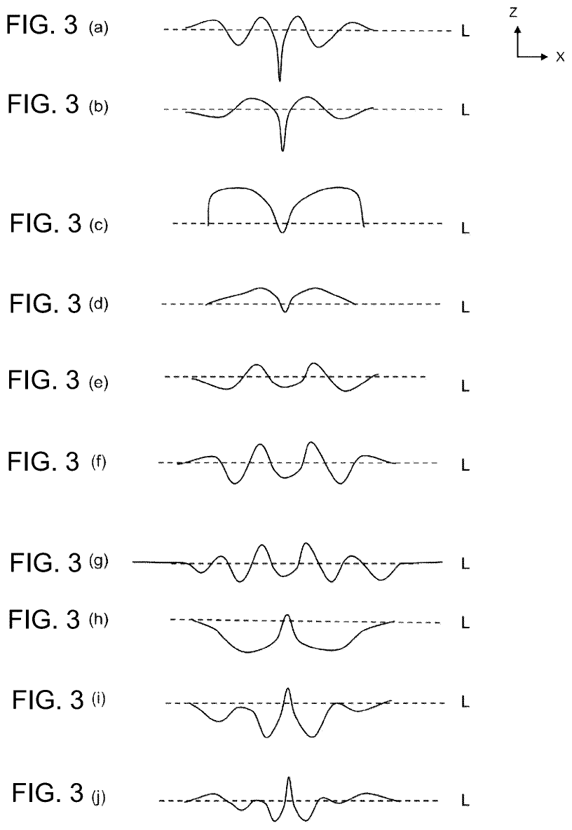

Next, Modified Example 1 of the shape of the unevenness 2a will be described with reference to FIGS. 3(a)-3(j). In FIGS. 3(a)-3(j), all of FIGS. 3(a) to 3(j) are views illustrating a cross-sectional shape when the plane shape of the unevenness 2a is concentrically formed.

In the uneven shapes illustrated in FIGS. 3(a) to 3(j), the effects of the invention of the present application can be more effectively exerted as the number of mountains and valleys of an unevenness is larger (manufacturing methods of these shapes will be described later).

### Second Embodiment

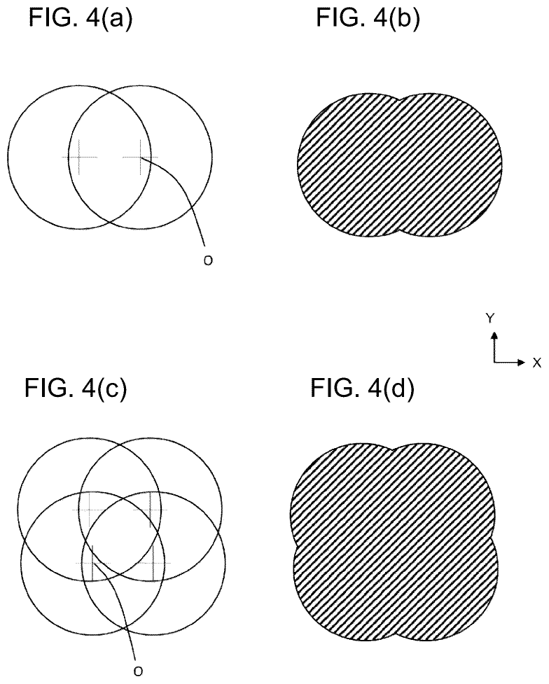

Next, the shape of the unevenness 2a will be described as a second embodiment with reference to FIGS. 4(a)-4(d). FIGS. 4(a)-4(d) are views of modified examples when the plane shape of the unevenness 2a is not concentric. The unevenness 2a in the present disclosure can be formed by providing a laser modified part to the glass substrate as described later. When a laser irradiation position O is set at two locations as illustrated in FIG. 4(a), a range in which an unevenness is formed can be formed not in a concentric range but as a horizontally long plane shape as illustrated in FIG. 4(b).

Further, when a laser irradiation position O is set at four locations as illustrated in FIG. 4(c), a range in which an unevenness is formed can be formed not in a concentric range but as a square planar shape without corners as illustrated in FIG. 4(d).

The number of laser irradiations and their positional relationship are not limited to those described above, and an optional number of laser irradiations and an optional positional relationship can be selected.

Further, an independent uneven part can be naturally provided at a plurality of locations such that the respective plane shapes of the uneven parts do not overlap with one another.

In this manner, the effects of the invention of the present application can be more effectively exerted by forming a plurality of uneven parts X having complicated shapes on the bottom surface.

### <Effects>

By providing the unevenness 2a, the unevenness 3a, and the unevenness 7a to the bottom surface part A of the through electrode and at least one of the hydrofluoric acid resistant metal layer 3, the first seed layer, and the second seed layer 7 which are adjacent to the bottom surface part A of the through electrode as illustrated in FIG. 1, the contact area between the bottom surface of the through electrode provided to the glass substrate and the adjacent hydrofluoric acid resistant metal layer 3, first seed layer, and second seed layer 7 can be increased. Therefore, the increase in the contact area improves the connection reliability on the bottom of the through electrode.

In particular, the occurrence of disconnection and resistance increases in a thermal cycle test (TCT) can be suppressed.

The quantitative effects thereof will be described in detail by also comparing with Comparative Examples, following to the description of Examples below.

### EXAMPLE 1

Next, a method of manufacturing the multilayer wiring substrate will be described as Example 1 according to the first embodiment with reference to FIGS. 5(a)-5(c) to FIGS. 7(g)-7(k)

### (Step 1)

First, as illustrated in a of FIGS. 5(a)-5(c), a glass substrate 1 is prepared. The glass substrate 1 may be either non-alkali glass or alkali glass. Since the thickness after etching is 50 um to 300 μm, the thickness of the glass substrate is desirably 50 μm or more thicker than the thickness after etching. Further, for example, a glass substrate having a thickness of 300 μm can also be used.

### (Step 2)

Next, as illustrated in FIG. 5(b), a second surface side as the lower surface side of the glass substrate is irradiated with a laser to form a laser modified part 2 from which a through glass via starts. The laser modified part 2 is formed so as to extend from the second surface toward the upper side, for example, in a vertical direction and reach a first surface to the laser modified part 2. At this time, a green pulse laser is used for adjusting the pulse width, power, and the like to form an uneven shape having a maximum height of 0.7 μm and width of 1.2 μm on the first surface.

It is noted that the laser for forming the unevenness may be, in place of a green pulse laser, a near-infrared pulse laser or the like.

The conditions of the pulse laser include pulse width, power, wavelength, and others. The pulse width is preferably 500 femtoseconds (fs) to 25 nanoseconds (ns). It is more preferably 500 fs or more and 50 ps or less. It is further preferably 1 ps to 20 ps and particularly preferably 5 to 15 ps.

On the contrary, when it is 25 ns or more, microcracks are likely to occur on the periphery of the modified part during laser irradiation. Further, when it is 500 fs or less, the cost of a laser irradiation device significantly increases.

The energy of laser is not particularly limited but is desirably energy corresponding to the composition of the glass substrate and the dimension of the modified part to be formed. The power of the laser is favorably, for example, 1 to 1000 μJ/pulse. Further, it is more preferably 5 μJ/pulse to 200 μJ/pulse. A longer modified part 65 can be formed by increasing laser energy, but microcracks on the periphery of the modified part tend to increase in proportion to an increase in laser pulse energy.

The laser to be used may include a ND:YGG laser, a harmonic of ND:YVO4 laser, or a harmonic of ND:Y1F laser. In this case, examples of the harmonic include a second harmonic and a third harmonic. The wavelength of the laser may be appropriately set, as long as it can be adjusted to a desired irradiation spot. However, since wavelengths in the vicinity of 266-268 nm for the fourth harmonic lead to an increase in cost of a laser irradiation device, the wavelength is preferably and desirably in a range of 355 nm to 1064 nm.

### (Step 3)

Next, as illustrated in FIG. 5(c), a hydrofluoric acid resistant metal layer 3 is formed in a range of 10 nm or more and 500 nm or less on the first surface of the glass substrate. Thereafter, a copper coating film is formed as a first seed layer in a range of 100 nm or more and 500 nm or less on the hydrofluoric acid resistant metal layer 3.

The material of the hydrofluoric acid resistant metal layer 3 can be appropriately selected from, for example, chromium, nickel, and nickel chromium. Since the hydrofluoric acid resistant metal layer 3 is formed following the shape of the uneven part of the glass substrate 1, an uneven shape similar to that of the glass substrate 1 is also transferred and formed on the hydrofluoric acid resistant metal layer 3.

### (Step 4)

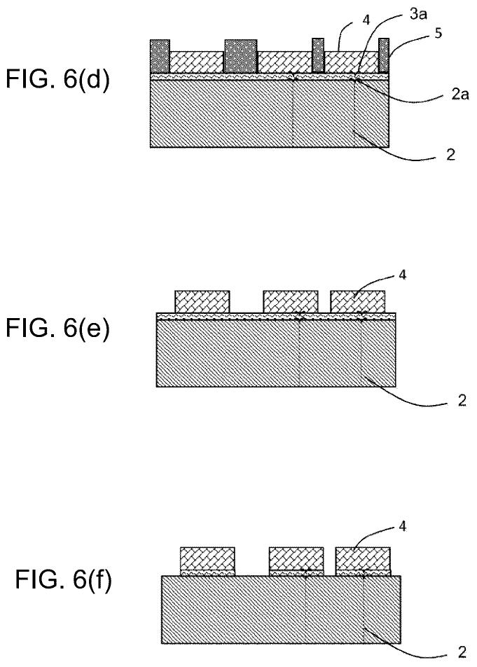

Next, as illustrated in FIG. 6(d), an inverse pattern of a wiring pattern is formed by a photoresist 5. Although a dry photoresist is generally used as a photoresist material, a photosensitive film such as a direct writing type RD-1225 manufactured by Hitachi Chemical Co., Ltd. may be used. For forming a pattern by a direct writing type photosensitive film, a photosensitive film is firstly subjected to a laminating treatment, and a set pattern is subsequently written and developed so that the seed layer formed in Step 3 is exposed in a desired pattern.

### (Step 5)

Next, this exposed seed layer is fed with power to form a wiring layer 4 having a thickness of 2 μm or more and 10 μm or less by electrolytic copper plating. Then, as illustrated in FIG. 6(e), the dry film resist no longer needed after completion of electrolytic copper plating is dissolved away.

### (Step 6)

Next, as illustrated in FIG. 6(f), the seed layer is removed by etching to form a wiring.

### (Step 7)

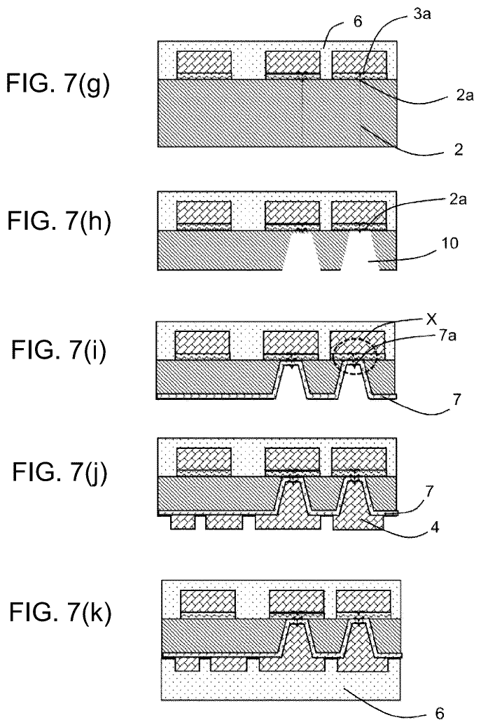

Next, as illustrated in FIG. 7(g), an insulating resin 6 is laminated on the wiring.

### (Step 8)

Next, as illustrated in FIG. 7(h), etching is performed from the second surface of the glass substrate with a hydrogen fluoride solution. Glass in a portion where the laser modified part 2 is not formed is etched with the hydrogen fluoride solution and thinned in parallel to the first surface of the glass substrate. The laser modified part 2 is dissolved preferentially in the non-modified part to form a through glass via. In this manner, the glass substrate is thinned, while the through glass via is formed. That is, thinning and formation of a through glass via 10 are performed in a single etching treatment. The lower surface of the thinned glass substrate is a second surface on which a second-surface wiring layer is formed.

The etching amount by the hydrogen fluoride solution may be appropriately determined depending on the thickness of the glass device. For example, if the glass substrate used in Step 1 has a thickness of 400 μm, the etching amount is preferably in a range of 100 μm or more and 350 μm or less.

The thinned glass substrate 1 preferably has a thickness of 50 μm or more and 300 μm or less.

When the through glass via is formed, an unevenness 2a transferred and formed on the hydrofluoric acid resistant metal layer is exposed on the bottom surface of the through glass via.

### (Step 9)

Next, as illustrated in FIG. 7(i), a second seed layer 7 is formed by sputtering from the second surface side on which the through glass via 10 is formed. The uneven shape of the hydrofluoric acid resistant metal layer 3 is transferred to the thus-formed second seed layer, and an unevenness X is formed in the bottom surface part of the through electrode.

### (Step 10)

Next, as illustrated in FIG. 7(j), a wiring layer 4 is formed on the second surface. Specifically, similarly to in Steps 4, 5, and 6, a pattern is formed by a dry film resist, and the second seed layer 7 is energized to form an electrolytic plated layer having a thickness of 2 μm or more and 10 μm or less.

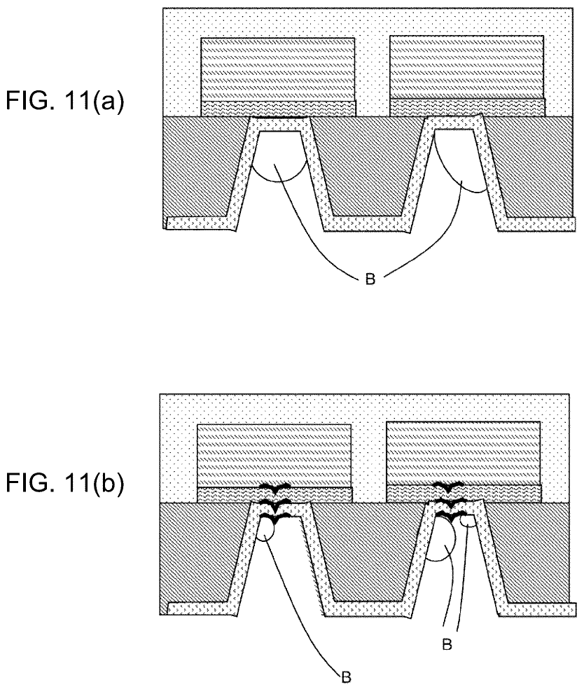

In the step of electrolytic plating, air bubbles are likely to accumulate on the bottom of the bottomed TGV, which is often an obstacle to the formation of a complete through electrode. However, in the embodiments of the present disclosure, the uneven shape is formed on the second seed layer 7, which serves as a starting point from which air bubbles are released, and plating failure caused by air bubbles can be reduced. This point will be described in detail later using FIGS. 11(a) and 11(b).

After electrolytic plating, excess dry film resist is dissolved to form a through electrode 9. The seed layer no longer needed thereafter is removed, and the insulating resin 6 is laminated on the through electrode.

### (Step 11)

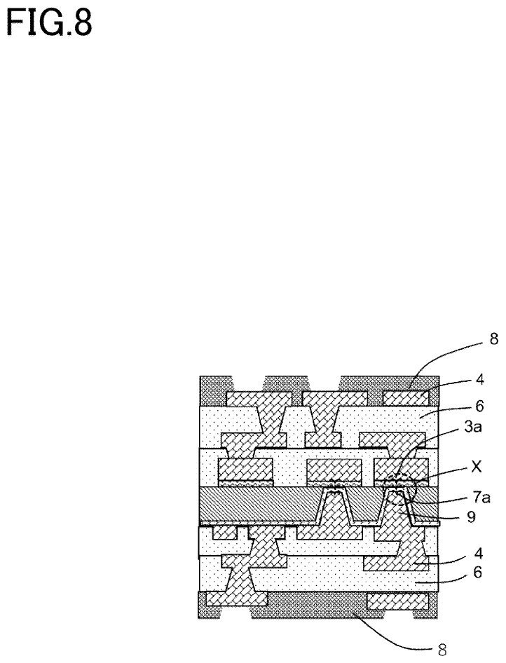

Next, as illustrated in FIG. 8, a multilayer wiring substrate having an optional number of layers is formed by a known method. It is noted that an outer layer protective film such as a solder resist 8 may be formed as a coat as the outermost layer, and an opening part may be provided if an external connection terminal or the like is needed.

Thus, a glass wiring substrate can be formed in which long-term reliability of the TGV part is improved, and via filling failure during plating is reduced.

### <Details of Unevenness>

Next, a detailed structure of the unevenness in Example 1 will be described with reference to FIGS. 9(a)-9(d) and FIGS. 10(f)-10(h). FIGS. 9(a)-9(d) and FIGS. 10(f)-10(h) are cross-sectional views for explaining manufacturing steps of the unevenness in the bottom surface part of the through electrode.

In FIGS. 9(a)-9(d) and FIGS. 10(f)-10(h), each of the hydrofluoric acid resistant metal layer 3, a first seed layer 11, and the second seed layer 7 has a film thickness of 30 to 200 nm. Further, the dimension of the uneven shape is 0.5 to 20 μm in width, and each of the maximum swelling height H1 of the unevenness and the maximum concave depth H2 of the unevenness is 0.5 to 5 μm. Therefore, as illustrated in FIGS. 9(a)-9(d) and FIGS. 10(f)-10(h), the uneven shapes of the hydrofluoric acid resistant metal layer 3 and the first seed layer 11 are larger than the unevenness of the glass substrate by one coating layer and two coating layers, and the shapes of the unevennesses, which are transferred from the unevenness of the glass substrate, are not completely the same but similar, or the presence or absence of unevenness is common. In brief, the formed unevennesses have a common element in the position on the XY plane, shape, size, and the like and conform to one another.

On the other hand, the second seed layer 7 similarly has a shape smaller by about one layer.

As illustrated in FIG. 9(a), a glass substrate 1 is firstly irradiated with a laser for forming a modified part, and the laser modified part 2 reaching a first surface is formed, so that an unevenness 2a is formed in a bottom surface part.

Thereafter, as illustrated in FIG. 9(b), a hydrofluoric acid resistant metal layer 3 is formed on the upper side of the unevenness 2a.

It is noted that the hydrofluoric acid resistant metal layer 3 was formed after the unevenness was formed in the glass substrate 1 by laser here, but the hydrofluoric acid resistant metal layer 3 may be formed on the glass substrate 1 at a stage before irradiating the glass substrate 1 with a laser, and the glass substrate 1 may be thereafter irradiated with a laser to concurrently form unevenness in the glass substrate 1 and the hydrofluoric acid resistant metal layer 3.

Thereafter, as illustrated in FIG. 9(c), a first seed layer 11 is formed on the hydrofluoric acid resistant metal layer 3.

A plurality of first seed layers may be provided, or the first seed layer may be omitted if unnecessary.

Thereafter, as illustrated in FIG. 9(d), the first seed layer is used to form a wiring layer 4 by electrolytic plating. An example of the method of forming the wiring layer 4 is a so-called semi-additive process of forming a copper wiring layer by electrolytic plating or the like after forming a pattern by photolithography, and thereafter removing unnecessary portions by etching.

Next, after an insulating resin has been formed on the upper side of the wiring layer 4, the process proceeds to the formation of a TGV. The formation of a TGV is performed by removing the glass modified by laser with an etching liquid such as hydrofluoric acid. When etching has reached the hydrofluoric acid resistant metal layer 3, the etching ends, and a TGV is formed. Thus, the cross-sectional shape illustrated in FIG. 10(f) can be obtained. It is noted that in FIG. 10(f), the region on the lower side is a through glass via 10 (the overall view of the location illustrated in FIG. 10(f) is illustrated in FIG. 7(h)).

Subsequently, as illustrated in FIG. 10(g), a second seed layer is formed inside the through glass via 10. Note that it is mandatory to form the second seed layer 7 on the second surface of the glass substrate 1 excluding the through glass via and the side wall of the through glass via, but it is not mandatory when a conductor such as the hydrofluoric acid resistant metal layer 3 is formed on the bottom surface of the through glass via 10. Further, an etching stop layer such as the hydrofluoric acid resistant metal layer 3 on the bottom surface of the through glass via 10, the seed layer for electrolytic plating, and the like can be removed if unnecessary.

Next, as illustrated in FIG. 10(h), the wiring layer 4 is formed in the through glass via 10 by electrolytic plating. As the method of forming the wiring layer 4, a semi-additive process similar to that for the front surface, and the like can be used.

In a region where the unevennesses are formed in this manner, there is a region where a part of the wiring layer 4 provided on the upper side of the glass substrate 1 enters the lower side than the first surface of the glass substrate, and there is a region where the wiring layer 4 as a material constituting the through electrode enters the upper side than the first surface of the glass substrate.

### <Effects>

According to the embodiments of the present disclosure, a large uneven shape is formed in each layer such as the hydrofluoric acid resistant metal layer (etching stop layer), the first seed layer 11, or the second seed layer 7, in the bottom surface part of the through electrode. Therefore, the contact area between the layers increases, and adhesion of the layers on the bottom of the TGV is improved by the uneven shape serving as an anchor, with the result that connection reliability can be improved. The quantitative evaluation thereof will be described later.

Next, with reference to FIGS. 11(a) and 11(b), the effects in the electrolytic plating step, of providing unevenness on the surface of the bottom surface part of the through electrode of the present disclosure will be described.

In a state in which the through glass via 10 is formed, the wiring layer 4 is formed in the through glass via by electrolytic plating as illustrated in FIG. 7(i) to FIG. 7(j).

In this case, the shape of the bottom surface of the through glass via is such that since the thickness of the glass substrate 1 is 50 to 1000 μm with openings of diameter roughly roughly 50 to 200 μm, the aspect ratio between the thickness of the glass substrate 1 and the opening diameter is as high as 20 in some cases.

When the aspect ratio is high in this manner, a phenomenon is likely to occur in which during electrolytic plating, air bubbles generated in the electrolytic solution or air bubbles B drawn in when immersing a substrate in a liquid are not released from the through glass via. That is, as illustrated as an example in FIG. 11(a), the air bubbles B often grow large in such a manner as to cover the entirety of the through glass via 10. In such a case, the large size of air bubbles causes the air bubbles B to be hardly removed by external vibration, liquid flow, or the like, with the result that in portions where there are air bubbles B, electrolytic plating is insufficient, leading to the occurrence of defective products.

On the other hand, when the bottom surface of the through glass via has a projection of unevenness as in the embodiments of the present disclosure, when the glass substrate 1 is immersed in the plating solution, air bubbles B that cover the entire bottom surface of the through glass via are unlikely to occur.

It is considered that this is because, as illustrated in FIG. 11(b) the unevenness on the bottom surface of the through glass via makes it easier for bubbles to be separated and prevented from growing into large bubbles. As a result, the size of air bubbles decreases, and removal of air bubbles by external vibration, liquid flow, and the like is easier compared to when no uneven parts exist. The quantitative evaluation thereof will also be described later.

Hereinafter, Example 2 to Example 6, in which the constituents of Example 1 described above are partly changed, will be described.

### EXAMPLE 2

Example 2 is a case in which in Example 1, the uneven shape has a maximum height (the value of H1 or H2 which is not smaller in FIG. 2(a)) of 0.9 μm and a width (W in FIG. 2(a)) of 1.8 μm. The pulse width, power, and the like were adjusted using a near-infrared pulse laser to change the size of the uneven shape. Otherwise, a wiring substrate of Example 2 was obtained in the same manner as Example 1.

### Example 3

Example 3 is an example of a case in which in Example 1, the uneven shape was formed at two locations. The uneven shape had a maximum height of 0.7 μm and a width of 1.2 μm. Irradiation with green pulse laser was performed at a pitch of 30 μm to form a long round via shape. Otherwise, a wiring substrate of Example 3 was obtained in the same manner as Example 1.

### EXAMPLE 4

Example 4 is an example of a case in which in Example 1, the plating of the TGV was formed with a filled via. The composition of the plating bath was changed to form a plated film such that the TGV was completely filled. Otherwise, a wiring substrate of Example 4 was obtained in the same manner as Example 1.

### EXAMPLE 5

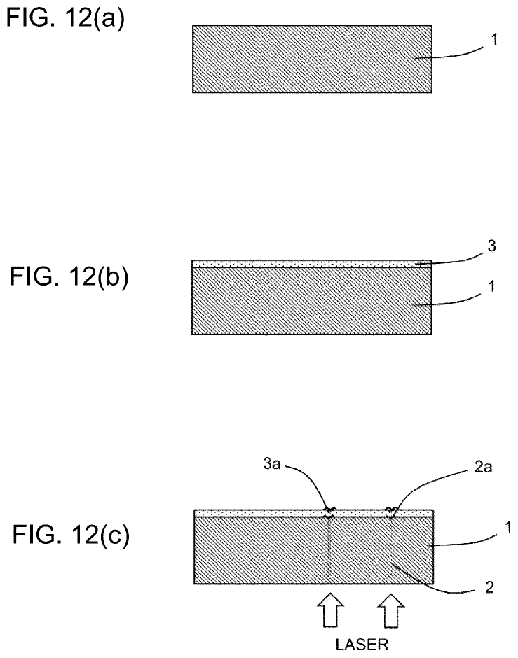

Example 5 is an example of a case in which in Example 1, the order of the irradiation with laser and the formation of the hydrofluoric acid resistant metal layer was changed. Specifically, as illustrated in FIGS. 12(a)-12(c), a glass substrate is firstly prepared in FIG. 12(a), and a hydrofluoric acid resistant metal layer is formed in FIG. 12(b). Thereafter, as illustrated in FIG. 12(c), a laser modified part and an uneven shape were formed. For the size of the uneven shape, the laser conditions were adjusted to have a maximum height of 0.7 μm and a width of 1.2 um which is the same as Example 1. The uneven shape was formed on the glass substrate and the hydrofluoric acid resistant metal layer. Otherwise, a wiring substrate of Example 5 was obtained in the same manner as Example 1.

### EXAMPLE 6

Example 6 is a case in which in Example 1, the direction of the laser irradiation was changed downward. The first surface side of the glass substrate was irradiated with a laser to form, on the first surface, an uneven shape having a maximum height of 1.0 μm and a width of 2.1 μm. Otherwise, a wiring substrate of Example 6 was obtained in the same manner as Example 1.

Hereinafter, Comparative Examples for verifying a difference in effects from the above-described Examples will be described.

### COMPARATIVE EXAMPLE 1

Comparative Example 1 is an example of a case in which in Example 1, the laser irradiation did not penetrate to the first surface of the glass substrate 1, but terminated within the glass substrate, and an uneven shape was not formed on the first surface side. Such a modified area adjustment is enabled by controlling the focal position of the laser. Otherwise, a wiring substrate of Comparative Example 1 was obtained in the same manner as Example 1. Modification area adjustment

### COMPARATIVE EXAMPLE 2

In Comparative Example 1, the plating of the TGV was formed as a filled via, i.e., such that the TGV was completely filled. Such adjustment is enabled by adjusting the composition of the plating bath and the plating time. Otherwise, a wiring substrate of Comparative Example 2 was obtained in the same manner as Comparative Example 1.

### COMPARATIVE EXAMPLE 3

Comparative Example 3 is a case in which in Comparative Example 1, the focal position and power of the laser irradiation were adjusted to form the glass modified part only in the center part of glass. Comparative Example 3 is a case in which the modified part did not penetrate to both of the first surface and the second surface, and the laser irradiation was terminated on a part of the glass substrate so that the uneven shape was not formed on both of the first surface and the second surface. Specifically, only a 300 μm portion in the center of a glass plate having a thickness of 500 μm was modified. During hydrofluoric acid etching, the film thickness of glass uniformly decreases at first, but when reaching the modified part, the etching rate increases only in that portion so that a via is formed. When passing the modified part, etching proceeds uniformly again. Otherwise, a wiring substrate of Comparative Example 3 was obtained in the same manner as Comparative Example 1.

### COMPARATIVE EXAMPLE 4

Comparative Example 4 is an example of a case in which in Comparative Example 3, the second surface of the glass substrate was removed by polishing before the hydrofluoric acid etching. In Comparative Example 4, 120 μm of the second surface side of the glass substrate was removed by polishing, and thereafter hydrofluoric acid etching was performed. Since decreasing the film thickness of glass by polishing and the TGV by hydrofluoric acid etching were performed in separate steps, the shape stability of the TGV is improved. Otherwise, a wiring substrate of Comparative Example 4 was obtained in the same manner as Comparative Example 3.

### <Verification of Effects>

### (Thermal Cycle Test)

As a determination criteria of the connection reliability of the through electrode of the multilayer wiring substrate, a thermal cycle test (TCT) is generally used. In the TCT, the multilayer wiring substrate is repeatedly placed under environments of high temperature and low temperature such that stress is generated in each layer of the multilayer wiring substrate due to a difference in the thermal expansion coefficient, and it is possible to examine the tendency for wiring breakage to occur due to stress, particularly in the via part including the TGV.

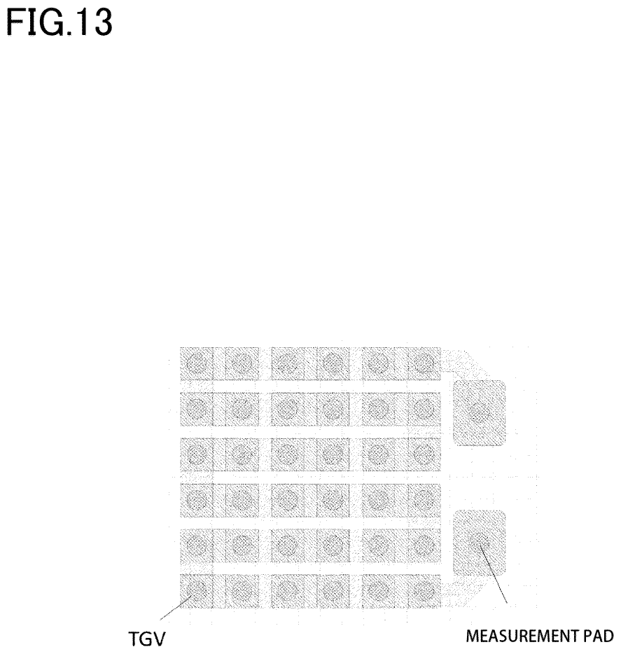

Specifically, a daisy chain which shuttles from the first layer to the sixth layer via the TGV of the six-layer wiring substrate illustrated in FIG. 8 was prepared for 36 TGVs as illustrated in FIG. 13 to obtain a test pattern, and 50 test patterns were prepared and subjected to a TCT test to count the number of occurrences of wiring breakage.

TCT conditions: −55° C. to 125° C., wiring width: 140 μm, via diameter: φ80 μm, pad width: 140 μm.

Determination: Excellent for no disconnected lines, Good for five or fewer disconnected lines, and Poor for more than five disconnected lines.

Further, evaluation was also performed on the occurrence frequency of defects caused by air bubbles during plating.

### (Evaluation of Plating)

Hundred thousand φ80 μm TGVs were formed in a 320×400 mm substrate, and the ratio of unattached plating caused by air bubbles during plating in Step 10 was confirmed. As the treatment conditions of the substrate, the inside of the through glass via was subjected to a hydrophilizing treatment with plasma and washing with sulfuric acid before electrolytic plating was performed. Thereafter, the substrate having the TGV part was immersed in a copper sulphate plating solution for performing electrolytic plating to have a film thickness of 5 μm.

Determination: Excellent when failure ratio is 1% or less, Good when 10% or less, and Poor when more than 10%.

(Table 1) Results of thermal cycle (TCT) and plating reliability evaluation

TABLE 1

| | | | | | | | | | Laser conditions | | |
|---|---|---|---|---|---|---|---|---|---|---|---|
| | Unevenness of TGV | | | | Direction | | Result | | Pulse | | |
| | Height | Width | | | of laser | | Plating | TCT | width | Power | |
| Conditions | μm | μm | Number | Pitch | processing | Plating | evaluation | test | PS | μJ/pulse | Wavelength |
| Example 1 | 0.7 | 1.2 | 1 | — | Upward | Conformal | Excellent | Excellent | 20 | 80 | Green |
| Example 2 | 0.9 | 1.8 | 1 | — | Upward | Conformal | Excellent | Excellent | 20 | 100 | Near- |
| | | | | | | | | | | | infrared |
| Example 3 | 0.7 | 1.2 | 2 | 30 | Upward | Conformal | Excellent | Excellent | 20 | 80 | Green |
| | | | | μm | | | | | | | |
| Example 4 | 0.7 | 1.2 | 1 | — | Upward | Filled | Excellent | Good | 20 | 80 | Green |
| Example 5 | 0.7 | 1.2 | 1 | — | Upward | Conformal | Excellent | Good | 20 | 80 | Green |
| Example 6 | 1.0 | 2.1 | 1 | — | Downward | Conformal | Good | Good | 20 | 80 | Green |
| Comparative | None | None | None | None | Upward | Conformal | Poor | Poor | | | |
| Example 1 | | | | | | | | | | | |
| Comparative | None | None | None | None | Upward | Filled | Poor | Poor | | | |
| Example 2 | | | | | | | | | | | |
| Comparative | None | None | None | None | Upward | Conformal | Poor | Poor | | | |
| Example 3 | | | | | | | | | | | |
| Comparative | None | None | None | None | Upward | Conformal | Poor | Poor | | | |
| Example 4 | | | | | | | | | | | |

As described above, it could be confirmed in the thermal cycle (TCT) and the plating reliability evaluation that in Examples 1 to 6 of the present disclosure, a highly-reliable multilayer wiring substrate that has excellent thermal shock resistance compared to those without an unevenness can be provided by including the unevenness in the bottom surface part of the through electrode.

The embodiments of the present invention have been described above, but the present invention is not limited to the above-described embodiments, which can be variously modified within the range not departing from the spirit of the present invention.

### REFERENCE SIGNS LIST

1: Glass substrate; 2: Laser modified part; 2a: Unevenness formed on glass substrate; 3: Hydrofluoric acid resistant metal layer; 3a: Unevenness formed on hydrofluoric acid resistant metal layer; 4: Wiring layer; 5: Photoresist; 6: Insulating resin; 7: Second seed layer; 7a: Unevenness formed on second seed layer; 8: Solder resist; 9: Through electrode; 10: Through glass via; 11: First seed layer; 11a: Unevenness formed on first seed layer; 100: Multilayer wiring substrate; A: First surface of glass substrate; L: Level of first surface of glass substrate; X: Unevenness formed on bottom surface part.

What is claimed is:

1. A multilayer wiring substrate, comprising:
a glass substrate provided with a through electrode, wherein
a bottom surface part of the through electrode provided to the glass substrate includes an unevenness in which an absolute value of a height difference from a first surface of the glass substrate is ±0.5 μm or more and 5 μm or less.

2. The multilayer wiring substrate of claim 1, wherein
the unevenness has a width of 0.5 μm or more and 20 μm or less.

3. The multilayer wiring substrate of claim 1, wherein
at least one of a hydrofluoric acid resistant metal layer, a first seed layer, and a second seed layer, which are adjacent to a bottom surface part of the through electrode, includes an unevenness conforming to the unevenness on a surface of the bottom surface part.

4. The multilayer wiring substrate of claim 1, wherein
in a region where the unevenness is formed, a region where a part of a wiring layer provided on an upper side of the glass substrate enters a lower side than the first surface of the glass substrate exists, and a region where a material constituting the through electrode enters an upper side than the first surface of the glass substrate.

5. The multilayer wiring substrate of claim 1, wherein
the unevenness of at least one of the hydrofluoric acid resistant metal layer, the first seed layer, and the second seed layer, which are adjacent to the bottom surface part of the through electrode, is transferred and formed from the unevenness of the bottom surface part of the through electrode.

6. The multilayer wiring substrate of claim 1, wherein
the bottom surface of one through electrode includes the unevenness at a plurality of locations.

7. The multilayer wiring substrate of claim 1, wherein
the unevenness of the bottom surface part is formed by irradiating the glass substrate with a laser to change a shape of the glass substrate.

8. A method of manufacturing a multilayer wiring substrate, comprising the steps of:
a first step of irradiating a glass substrate having a first surface and a second surface with a laser to form a modified part reaching the first surface in the glass substrate and form, on the first surface of the glass substrate, an unevenness having a width of 0.5 μm or more and 20 μm or less;
a second step of forming, on the first surface of the glass substrate, a hydrofluoric acid resistant metal layer and/or a first seed layer on each of which the unevenness is transferred and formed;
a third step of forming a wiring pattern on an upper side of the hydrofluoric acid resistant metal layer and/or the first seed layer;
a fourth step of etching the modified part from the second surface of the glass substrate using an etching liquid to form a through glass via;
a fifth step of forming, on a surface of the through glass via, a second seed layer on which the unevenness is transferred and formed; and
a sixth step of energizing the second seed layer to perform an electrolytic plating treatment.

9. A method of manufacturing a multilayer wiring substrate, comprising the steps of:
a first step of forming a hydrofluoric acid resistant metal layer and/or a first seed layer on a first surface of a glass substrate having a first surface side and a second surface side;
a second step of irradiating a second surface side of the glass substrate with laser to form a modified part reaching the first surface of the glass substrate and form, on the first surface of the glass substrate and on the hydrofluoric acid resistant metal layer and/or the first seed layer, an unevenness having a width of 0.5 μm or more and 20 μm or less;
a third step of forming a wiring pattern on an upper side of the hydrofluoric acid resistant metal layer and/or the first seed layer;
a fourth step of etching the modified part from the second surface of the glass substrate with an etching liquid to form a through glass via;
a fifth step of forming, on a surface of the through glass via, a second seed layer on which the unevenness is transferred and formed; and
a sixth step of energizing the second seed layer to perform an electrolytic plating treatment.

10. A method of manufacturing a multilayer wiring substrate, wherein
in the method of manufacturing a multilayer wiring substrate of claim 8, the laser has a laser pulse width of 500 femtoseconds to 25 nanoseconds and a laser transmission wavelength of 355 nm or more and 1064 nm or less.

11. A method of manufacturing a multilayer wiring substrate, wherein
in the method of manufacturing a multilayer wiring substrate of claim 8, the laser has a laser pulse width of 500 femtoseconds to 50 picoseconds.

12. A method of manufacturing a multilayer wiring substrate, wherein
in the method of manufacturing a multilayer wiring substrate of claim 9, the laser has a laser pulse width of 500 femtoseconds to 25 nanoseconds and a laser transmission wavelength of 355 nm or more and 1064 nm or less.

13. A method of manufacturing a multilayer wiring substrate, wherein
in the method of manufacturing a multilayer wiring substrate of claim 9, the laser has a laser pulse width of 500 femtoseconds to 50 picoseconds.
